(19) United States
(12) Patent Application Publication
(10) Pub. No.: US 2007/0247204 A1
(43) Pub. Date: Oct. 25, 2007

(54) START UP CIRCUIT WITHOUT STANDBY CURRENT

(76) Inventor: Yang-Chen Hsu, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/379,800

(22) Filed: Apr. 24, 2006

(51) Int. Cl. H03K 3/02

(52) U.S. Cl. 327/198

(57) ABSTRACT

A start up circuit includes: a NOT gate; a capacitor coupled to an output of the NOT gate; a first switch for determining whether or not to couple an input of the NOT gate to an operating voltage source according to the output of the NOT gate; a control circuit for switching logic level of the input of the NOT gate when the input of the NOT gate is coupled to the operating voltage source over a predetermined period; and a start signal generator coupled to the NOT gate for generating at least one start up signal according to the input or the output of the NOT gate.

### BACKGROUND OF THE INVENTION

1. Field of the Invention

The present invention relates start up circuits, and more particularly, to start up circuits without standby current.

2. Description of the Prior Art

A start up circuit is one of the basic components of various circuitries. Generally, analog circuits tend to consume more standby current in comparison with digital circuits.

For improving power efficiency and for other reasons, many electronic devices or integrated circuits are designed to consume the least amount of power possible. Therefore, an important issue for system design becomes how to effectively reduce the power consumption of the start circuit. For example, two different start up circuits without standby current are disclosed in U.S. Pat. No. 5,570,050 and U.S. Pat. No. 6,404,252. However, these two conventional start up circuits proposed by the above documents have complex circuitry architecture. In view of the hardware cost, it can be appreciated that a substantial need exists for start up circuits with further simplified architecture.

### SUMMARY OF THE INVENTION

It is therefore an objective of the claimed invention to provide a start up circuit having a simplified architecture and that requires no standby current.

An exemplary embodiment of a start up circuit is disclosed comprising: a NOT gate; a capacitor coupled to an output of the NOT gate; a first switch for determining whether or not to couple an input of the NOT gate to an operating voltage source according to the output of the NOT gate; a control circuit for switching logic level of the input of the NOT gate when the input of the NOT gate is coupled to the operating voltage source over a predetermined period; and a start signal generator coupled to the NOT gate for generating at least one start up signal according to the input or the output of the NOT gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a simplified block diagram of a start up circuit according to an exemplary embodiment of the present invention.

FIG. 2 is a circuitry diagram of the start up circuit of FIG. 1 according to a preferred embodiment.

FIG. 3 is a timing diagram illustrating the operation of the start up circuit of FIG. 2 in accordance with an exemplary embodiment.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

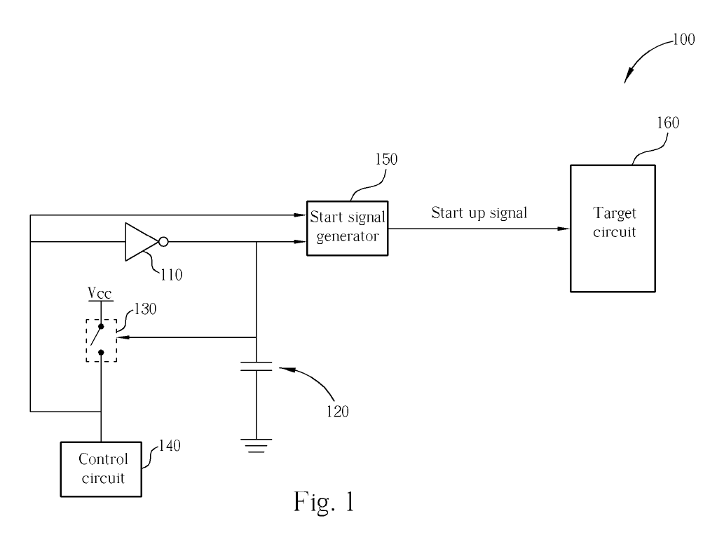

Please refer to FIG. 1, which shows a simplified block diagram of a start up circuit 100 according to an exemplary embodiment of the present invention. As shown, the start up circuit 100 comprises a NOT gate 110; a capacitor 120 coupled to an output of the NOT gate 110; a first switch 130 for determining whether or not to couple an input of the NOT gate 110 to an operating voltage source Vcc according to the output of the NOT gate 110; a control circuit 140 for switching logic level of the input of the NOT gate 110 when the input of the NOT gate 110 is coupled to the operating voltage source Vcc over a predetermined period; and a start signal generator 150 coupled to the NOT gate 110 for generating at least one start up signal to a target circuit 160 according to the input or the output of the NOT gate 110. In practice, the target circuit 160 may be an analog circuit, a digital circuit, or a hybrid circuit.

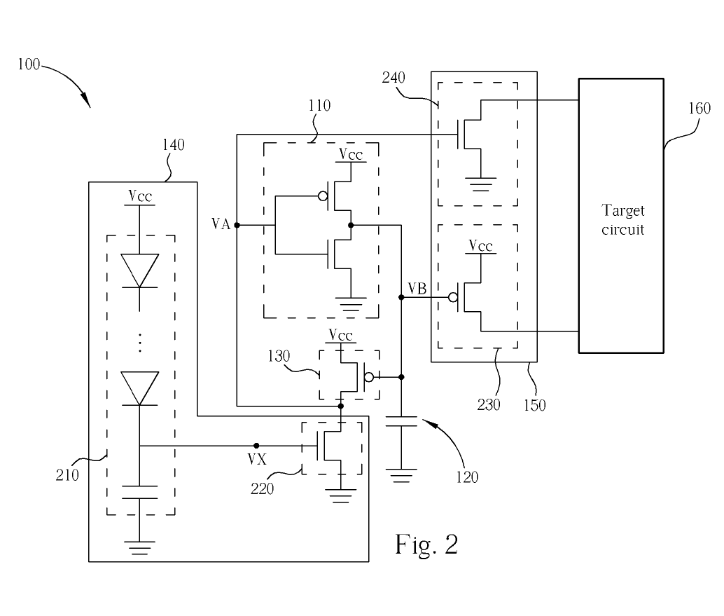

FIG. 2 is a circuitry diagram of the start up circuit 100 according to a preferred embodiment. In this embodiment, the control circuit 140 comprises a timing decision unit 210 and a second switch 220, and the start signal generator 150 comprises a current source 230 and a current sink 240. As shown in FIG. 2, the timing decision unit 210 of this embodiment is implemented by a plurality of cascaded diodes cooperating with a capacitor, in which the plurality of cascaded diodes function as the load of the operating voltage source Vcc. The timing decision unit 210 is arranged for generating a control voltage VX according to voltage supplied by the operating voltage source Vcc. The second switch 220 determines whether or not to switch the logic level of the input of the NOT gate 110 according to the control voltage VX.

In this embodiment, the first switch 130 of the start up circuit 100 is realized by a PMOS transistor with a gate terminal coupling to the output of the NOT gate 110, and the second switch 220 of the control circuit 140 is realized by a NMOS transistor with a gate terminal coupling to the control voltage VX. Accordingly, when the control voltage VX reaches a threshold voltage TH1 of the gate terminal of the NMOS transistor being the second switch 220, the second switch 220 turns on to couple the input of the NOT gate 110 to the ground voltage.

In the start up circuit 100, the NOT gate 110 and the first switch 130 form a positive feedback loop. When the operating voltage source Vcc is just activated, both the input and output of the NOT gate 110 start to charge. However, since the output of the NOT gate 110 is coupled to the capacitor 120, the charge speed of the input of the NOT gate 110 is higher than that of the output of the NOT gate 110. On the other hand, once the operating voltage source Vcc is activated, the output voltage of the operating voltage source Vcc starts at zero volts and gradually rises until a normal operating level is reached. The plurality of cascaded diodes of the timing decision unit 210 cause a voltage drop effect, so the increase of the control voltage VX generated by the timing decision unit 210 lags the increase of the output voltage of the operating voltage source Vcc. In other words, when the first switch 130 couples the input of the NOT gate 110 to the operating voltage source Vcc over a predetermined period, the second switch 220 of the control circuit 140 turns on to couple the input of the NOT gate 110 to the ground voltage. In one aspect, the switching timing of the second switch 220 is determined by the delay amount provided by the timing decision unit 210.

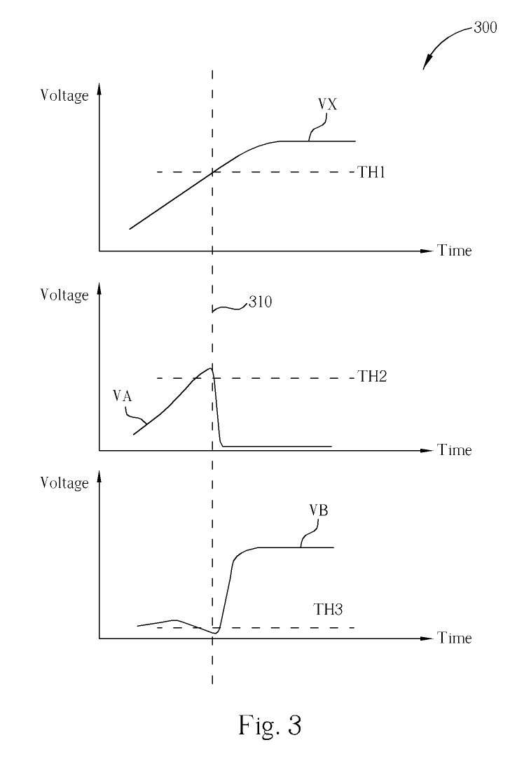

Please refer to FIG. 3, which depicts a timing diagram 300 illustrating the operation of the start up circuit 100 in accordance with an exemplary embodiment. As in the foregoing descriptions, when the operating voltage source Vcc is activated, the control voltage VX generated from the timing decision unit 210 gradually increases from zero volts. But the increase speed of the control voltage VX lags the output voltage of the operating voltage source Vcc by a predetermined period. Before a time point 310, since the control voltage VX does not reach the threshold voltage TH1 of the gate terminal of the NMOS transistor being the second switch 220, the second switch 220 remains in open status. During this period, the input of the NOT gate 110 is coupled to the operating voltage source Vcc via the first switch 130. As a result, an input voltage VA of the NOT gate 110 gradually increases as the output voltage of the operating voltage source Vcc before the time point 310.

When the input voltage VA of the NOT gate 110 reaches a first predetermined value, the current sink 240 of the start signal generator 150 is enabled to sink current. As shown in FIG. 2, the current sink 240 of this embodiment comprises a NMOS transistor with a gate terminal coupling to the input of the NOT gate 110. Therefore, when the input voltage VA of the NOT gate 110 reaches a threshold voltage TH2 of the gate terminal of the NMOS transistor in the current sink 240, the current sink 240 starts to sink current. On the other hand, when an output voltage VB of the NOT gate 110 reaches a second predetermined value, the current source 230 of the start signal generator 150 is enabled to provide current to the target circuit 160. In this embodiment, the current source 230 comprises a PMOS transistor with a gate terminal coupling to the output of the NOT gate 110. Accordingly, once the output VB of the NOT gate 110 falls below a threshold voltage TH3 of the gate terminal of the PMOS transistor in the current source 230, the current source 230 starts to supply current to the target circuit 160.

At the time point 310, since the control voltage VX generated from the timing decision unit 210 reaches the threshold voltage TH1 of the gate terminal of the NMOS transistor of the second switch 220, the second switch 220 couples the input of the NOT gate 110 to ground so as to switch the logic levels of both the input and output of the NOT gate 110. That is, the input of the NOT gate 110 is switched from logic 1 to logic 0, and the output of the NOT gate 110 is switched from logic 0 to logic 1. As a result, no standby current is consumed because the start signal generator 150 stops outputting start up signals.

In addition, the disclosed architecture further ensures that the start up signals provided by the start signal generator 150 are full swing signals so that the target circuit 160 can operate normally after it is activated.

Please note that in the foregoing embodiment, the timing decision unit 210 utilizes the plurality of cascaded diodes as the load of the operating voltage source Vcc. This is merely an embodiment rather than a restriction of the practical implementations. For example, the plurality of cascaded diodes can be replaced by a plurality of cascaded transistors (e.g., PMOS transistors or NMOS transistors).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A start up circuit comprising:
a NOT gate;
a capacitor coupled to an output of the NOT gate;
a first switch for determining whether or not to couple an input of the NOT gate to an operating voltage source according to the output of the NOT gate;
a control circuit for switching logic level of the input of the NOT gate when the input of the NOT gate is coupled to the operating voltage source over a predetermined period; and
a start signal generator coupled to the NOT gate for generating at least one start up signal according to the input or the output of the NOT gate.

2. The start up circuit of claim 1, wherein the control circuit comprises:
a timing decision unit for generating a control voltage according to voltage supplied by the operating voltage source; and
a second switch coupled to the timing decision unit and the NOT gate for coupling the input of the NOT gate to a predetermined level to switch the logic level of the input of the NOT gate when the control voltage reaches a threshold.

3. The start up circuit of claim 2, wherein the timing decision unit comprises a plurality of cascaded transistors being the load of the operating voltage source.

4. The start up circuit of claim 2, wherein the timing decision unit comprises a plurality of cascaded diodes being the load of the operating voltage source.

5. The start up circuit of claim 2, wherein the second switch is a transistor.

6. The start up circuit of claim 1, wherein the first switch couples the input of the NOT gate to the operating voltage source when the logic level of the output of the NOT gate reaches a predetermined value.

7. The start up circuit of claim 2, wherein the first switch is a transistor.

8. The start up circuit of claim 1, wherein the start signal generator comprises:
a current sink that is enabled to sink current when the input voltage of the NOT gate reaches a first predetermined value.

9. The start up circuit of claim 8, wherein the start signal generator comprises:
a current source that is enabled to supply current when the output voltage of the NOT gate reaches a second predetermined value.

10. The start up circuit of claim 1, wherein the start signal generator comprises:
a current source that is enabled to supply current when the output voltage of the NOT gate reaches a second predetermined value.
